(19) United States
(12) Patent Application Publication
(10) Pub. No.: US 2024/0001939 A1
(43) Pub. Date: Jan. 4, 2024

(54) METHOD FOR MONITORING FAILURE OF MOTOR IN A CAR BASED ON SCALING ALGORITHM AND SYSTEM USING THE SAME

(71) Applicants: SKAIChips Co., Ltd., Suwon-si (KR); Research & Business Foundation SUNGKYUNKWAN UNIVERSITY, Suwon-si (KR)

(72) Inventors: Kang Yoon LEE, Seoul (KR); Dong Gyun KIM, Suwonsi (KR); Dae Young CHOI, Suwon-si (KR); Jong Wan JO, Suwon-si (KR); Young Gun PU, Suwon-si (KR)

(73) Assignees: SKAIChips Co., Ltd., Suwon-si (KR); Research & Business Foundation SUNGKYUNKWAN UNIVERSITY, Suwon-si (KR)

(21) Appl. No.: 18/216,685

(22) Filed: Jun. 30, 2023

(30) Foreign Application Priority Data
Jun. 30, 2022 (KR) 10-2022-0080810

(51) Int. Cl. B60W 50/02; G06N 20/00

(52) U.S. Cl. CPC B60W 50/0205; G06N 20/00; B60W 2050/021

(57) ABSTRACT

According to various embodiment of the present invention, in a diagnosis system including a sensing module that senses the state of a motor is installed in a car, disclosed are a method for determining failure of a motor in a car comprising the steps of: (a) acquiring sensed values by sensing the state variables of the motor by the sensing module; (b) extracting two or more feature values by converting the sensed values acquired by the sensing module; (c) converting the two or more feature values into scaled feature values based on at least one scaling algorithm; and (d) determining a state of the motor based on a learned labeling algorithm and the scaled feature value, and setting a label representing the state of the motor to the scaled feature value corresponding to the state of the motor.

### CROSS-REFERENCE TO RELATED APPLICATION(S)

This application claims priority from Korean Patent Application No. 10-2022-0080810, filed on Jun. 30, 2022, in the Korean Intellectual Property Office, the disclosure of which is incorporated herein by reference in its entirety.

### BACKGROUND

### 1. Field

The present invention relates to a method for monitoring failure of a motor in a car based on a scaling algorithm and a system using the same, more specifically, relates a method for scaling feature values extracted by converting sensed values of a motor in a car sensed by a sensing module while a diagnosis system including the sensing module which senses the state of the motor in the car is installed inside the car and determining failure of the motor by using some of the scaled feature value and a system using the same.

### 2. Description of Related Art

PHM (Prognostic and health management) is a technology to diagnose the state of a driving system and predict failure of the same. Although PHM has already been applied to automobiles, it was only used for an analysis by transferring data to an external cloud server, etc. through a network at a failure diagnosis center, etc., but it has never been implemented on a single chip inside a car.

In other words, rather than diagnosing the state of the car's driving system on the system inside the car (SoC), the state of the car is diagnosed through an external server. Accordingly, there is a problem in that it must be interlocked with an external server through a network, and it may be difficult to diagnose in real time.

In order to solve the above problem, the inventor proposes a method for determining failure of a motor in a car and a system using the same.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

The present invention may have the following objects.

The present invention is to provide a method and system for diagnosing the state and failure of a motor in a car through a diagnosis system installed inside the car.

In addition, the present invention is to provide a method and system for monitoring the state of a driving system in a car in real time using AI technology.

In addition, the present invention is to provide a method and system for predicting information related to lifetime as well when predicting failure of a driving system in a car.

However, the problem to be solved by the present invention is not limited to the above-mentioned problem, and other problems that are not mentioned will be clearly understood by those skilled in the art from the following description.

According to an embodiment of the present invention, a method for monitoring failure of a motor in a car based on a scaling algorithm when a system for monitoring failure of the motor is mounted in the car and includes a sensing module sensing the state of the motor, the method comprising: (a) acquiring sensed values by sensing the state variables of the motor by the sensing module; (b) extracting two or more feature values by converting the sensed values acquired by the sensing module; (c) converting the two or more feature values into scaled feature values based on at least one scaling algorithm; and (d) determining a state of the motor based on a learned labeling algorithm and the scaled feature value, and setting a label representing the state of the motor to the scaled feature value corresponding to the state of the motor.

According to a more illustrative embodiment, wherein the two or more feature values are extracted, setting a plurality of normalization times based on the extraction time unit value corresponding to a preset time interval; and determining a plurality of normalization intervals corresponding to a preset extraction time range value, each normalization interval includes each normalization time.

According to a more illustrative embodiment, wherein the two or more feature values are extracted, extracting first specific feature values included in the plurality of normalization intervals from among the two or more feature values; converting the first specific feature values into first scaled feature values based on the scaling algorithm; and determining the state of the motor based on the first scaled feature value.

According to a more illustrative embodiment, wherein the extraction time unit value and the extraction time range value are set, changing the start time of each of the plurality of normalization intervals; extracting second specific feature values included in the plurality of changed normalization intervals; converting the second specific feature values into second scaled feature values based on the scaling algorithm; and determining the state of the motor based on the second scaled feature value.

According to a more illustrative embodiment, wherein the step (c) further comprising: extracting a part of the scaled feature value corresponding to a predetermined range in relation to the numerical value of the scaled feature value.

According to a more illustrative embodiment, further comprising: (e) updating the labeling algorithm based on the feature values for which the label is set, and resetting the feature values that classify the state of the motor based on said updated labeling algorithm;

According to another embodiment of the present invention, a system for monitoring failure of a motor in a car based on a scaling algorithm, comprising: a sensing module for sensing a state variables of the motor in the car and acquiring sensed values; a motor state determination module for extracting two or more feature values by converting the sensed values acquired by the sensing module, and for converting the two or more feature values into scaled feature values based on at least one scaling algorithm, and for determining the state of the motor based on the learned labeling algorithm and the scaled feature value, and for setting a label representing the state of the motor to the scaled feature value corresponding to the state of the motor, wherein the system is mounted in the car.

Other features and aspects will be apparent from the following detailed description, the drawings, and the claims.

### BRIEF DESCRIPTION OF THE DRAWINGS

FIG. 1 is a diagram illustrating a schematic configuration of a diagnosis system according to an embodiment of the present invention.

FIG. 2 is a diagram illustrating a specific configuration of a diagnosis system according to an embodiment of the present invention.

FIG. 3 is a diagram illustrating a process of predicting a failure of a motor or determining safety thereof according to an embodiment of the present invention.

FIG. 4 is a diagram illustrating a learning process of an AI module according to an embodiment of the present invention.

FIG. 5 is a diagram illustrating a process of extracting feature values according to an embodiment of the present invention.

FIG. 6 is a diagram illustrating a process of extracting feature values for each extraction time unit according to an embodiment of the present invention.

Throughout the accompanying drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following detailed description of the present invention refers to the accompanying drawings that show, as examples, specific embodiments in which the present invention may be implemented. These embodiments are described in sufficient detail to enable those of ordinary skill in the art to implement the present invention. It should be understood that various embodiments of the present invention are different but are not mutually exclusive. For example, certain shapes, structures, and characteristics described herein may be implemented in other embodiments without departing from the spirit and scope of the present invention in connection with an embodiment. It should also be understood that the positions or arrangement of individual elements in each disclosed embodiment may be varied without departing from the spirit and scope of the present invention. Therefore, the following detailed description is not to be taken in a limiting sense, and the scope of the present invention is limited only by the appended claims along with the full scope of equivalents to which the claims are entitled when properly explained. In the drawings, like reference numerals refer to the same or similar functions throughout several aspects.

Hereinafter, exemplary embodiment of the present invention will be described in detail with reference to the accompanying drawings so that those of ordinary skill in the art can easily implement the present invention.

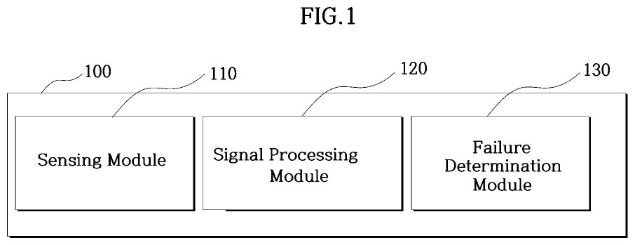

FIG. 1 is a diagram illustrating a schematic configuration of a diagnosis system according to an embodiment of the present invention.

As shown in FIG. 1, the diagnosis system 100 of the present invention may comprise a sensing module 110 and a motor state determination module 150. The motor state determination module 150 may comprise a signal processing module 120 and a failure determination module 130. The diagnosis system 100 can be installed inside a car and can perform several functions in the form of a System on Chip (SoC). That is, as a kind of semiconductor, the diagnosis system is able to play a role in diagnosing devices inside the car.

Specifically, the diagnosis system 100 of the present invention diagnoses the state of a driving system of a car, and in particular, is able to perform state diagnosis of electric motors, actuators, and the like.

In addition, although not shown in the figures, the diagnosis system 100 is able to include a communication unit, a processor, a storage unit, and the like.

The communication unit 120 may be implemented by various communication technologies. Namely, WIFI, WCDMA (Wideband CDMA), HSDPA (High Speed Downlink Packet Access), HSUPA (High Speed Uplink Packet Access), HSPA (High Speed Packet Access), Mobile WiMAX, WiBro, LTE (Long Term Evolution), 5G, 6G, bluetooth, IrDA (Infrared Data Association), NFC (Near Field Communication), Zigbee, a wireless LAN technology and the like may be applied. In addition, when connecting to the Internet to provide services, TCP/IP, which is a standard protocol for information transmission on the Internet, can be followed.

The storage unit may include at least one database to diagnose the state of the driving system of the car. For example, the storage unit may include artificial intelligence algorithms including at least some of artificial neural network algorithms, blockchain algorithms, deep learning algorithms, and mechanisms, operators, language models, and big data related thereto for the processing of operations performed by the diagnosis system 100, such as data sensing, failure factor extraction, cluster generation, linear classification, and/or Gaussian classification.

In addition, the storage unit may store a database including information related to the driving system of the car and at least some components thereof.

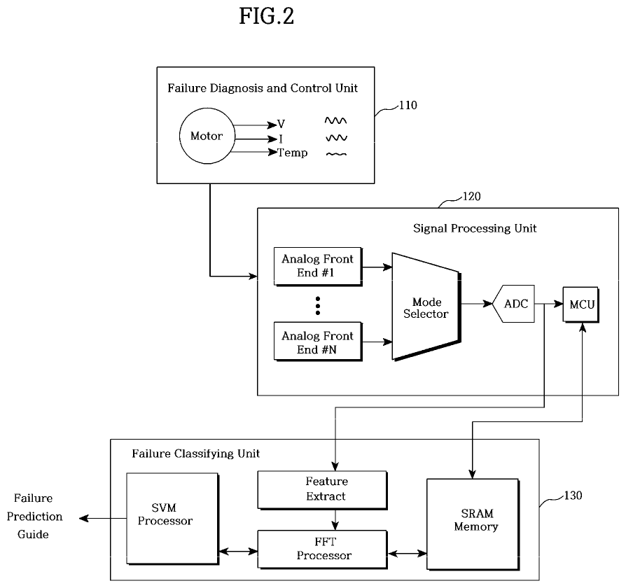

FIG. 2 is a diagram illustrating a specific configuration of a diagnosis system according to an embodiment of the present invention.

For reference, FIG. 2 is a diagram illustrating the diagnosis system (FIG. 1) of the present invention in more detail. According to one embodiment, a sensing module 110 corresponds to a failure diagnosis and control unit, and a signal processing module 120 corresponds to the signal processing unit, and a failure determination module 130 may correspond to a failure classifying unit.

Hereinafter, the process performed by the diagnosis system of the present invention will be described, focusing on the sensing module 110, the signal processing module 120, and the failure determination module 130.

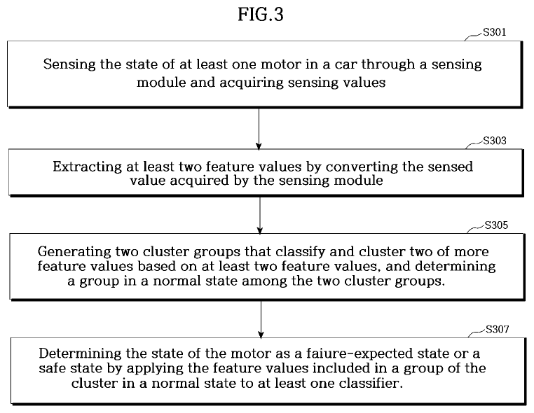

FIG. 3 is a diagram illustrating a process of predicting a failure of a motor or determining safety thereof according to an embodiment of the present invention.

First of all, it can be assumed that a diagnosis system 100 including a sensing module 110 for sensing the state of a motor in a car is installed in the car.

In the step S301, the diagnosis system 100 is able to sense the state of at least one motor in the car through the sensing module 110 and acquire sensed values. Herein, the sensing module 110 is able to measure state variables of motor, for example a temperature (Temp), a voltage (V), and/or a current (I) of the motor by using various sensors, and the measured values for state variables are the sensed values. For example, the acquired temperature, voltage, and/or current of the motor are analog values, as shown in FIG. 2

In the step S303, the diagnosis system 100 is able to extract a feature value by converting the sensed value acquired by the sensing module 110. The sensed values may be transmitted to the signal processing module 120 and the failure determination module 130 and converted into the feature value. Here, the signal processing module 120 may include a plurality of Analog Front End (AFEs), a Mode Selector, an Analog Digital Converter (ADC), an Micro Controller Unit (MCU), and the like.

Specifically, the sensed values (temperature, voltage, and/or current in analog form) acquired through the sensing module 110 may be transmitted to the ADC through several AFEs and converted into digital form. Here, each of the sensed values of temperature, voltage, and/or current, which is the measured values by sensing module 110, is transmitted through different AFEs and each of those may pass through an Amp, a Filter, and the like.

In addition, the sensed values (temperature, voltage, current) digitally converted may be transmitted to the failure determination module 130, passed through a Fast Fourier Transform (FFT) Processor and the like, and then extracted as the feature value by an Artificial Intelligence (AI) module (not shown) after passing through an FFT processor or the like. That is, the feature value may be determined by the AI module or the like based on the sensed values of motor, such as temperature, voltage, and/or current.

Herein, the AI module may be included in the failure determination module 130, and may exist on a chip of the diagnosis system 100 as a separate module depending on the case.

According to an embodiment of the present invention, the AI module may include an artificial neural network algorithm for processing feature extraction, normalized feature conversion, motor state determination, etc., blockchain algorithm, deep learning algorithm, and an artificial intelligence algorithm including at least some of mechanisms, operators, language models, and big data related thereto.

The feature value may be extracted by referring to the calculation formula as follows.

Feature Value=Ax+By+Cz+D

Here, A, B, C, D are variables (parameters), x is the converted value of the sensed temperature value, y is the converted value of the sensed voltage value, z is the converted value of the sensed current value. The converted values may be obtained by applying a Fourier transform to the sensed values. By setting some variables to 0, the feature value may be extracted from selected converted values.

The AI module may refer to the above formula. When temperature, voltage, current, and the like are measured by time period, the feature values may also be extracted by time period and form as a two-dimensional graph (x-axis: time, y-axis: feature value). The formula described above may vary depending on the setting.

That is, the feature value extracted from the sensed values may indicate the state of the corresponding motor by dividing it into several stages. Namely, when expressing the state of the motor as a normal state or an abnormal state, the feature value contains information capable of classifying each state of the motor into a plurality of stages. It is possible to determine a failure-expected period until failure of the motor is expected and/or a time point of failure of motor by using such information.

In the step S305, the diagnosis system 100 may convert two or more feature values into normalized (or scaled) data based on at least one normalization (or scaling) algorithm. Here, at least one scaling algorithm may be processed in the AI module.

According to an embodiment, the diagnosis system 100 may convert scales of a plurality of feature value extracted from sensors so that feature values or numerical values of feature values composed of various components have data within a specified unit and range.

For example, the diagnosis system 100 may convert numerical values representing the entire range of each of components constituting a system of feature values into numerical values within a designated range. For example, the scaling (or normalization) of feature values may be determined in various ranges based on setting information, such as 0 to 1, 0 to 10, 0 to 50, and −1 to 1.

According to an embodiment, the diagnosis system 100 may perform scaling of feature values based on Equation (1) proposed below.

Xn=(Xi−Xmin)/(Xmax−Xmin) (1)

Here, Xi is the input feature value, Xn is the feature value scaled for Xi, Xmax is the maximum value of the feature value, and Xmin is the minimum value of the feature value

According to Equation (1) described above, feature values may be converted into scaled feature values having a range of minimum and maximum values of [0, 1]. At this time, the diagnosis system 100 may scaling numerical values as independent variables (or feature data) among data for learning artificial intelligence algorithms for determining the state of a motor based on feature values.

In addition, the diagnosis system 100 is not limited to determining normalization data based on a scaling algorithm including Equation (1), and may convert input feature values by applying at least some of various scaling algorithms such as a standard scaler, a robust scaler, a minmax scaler, and the like.

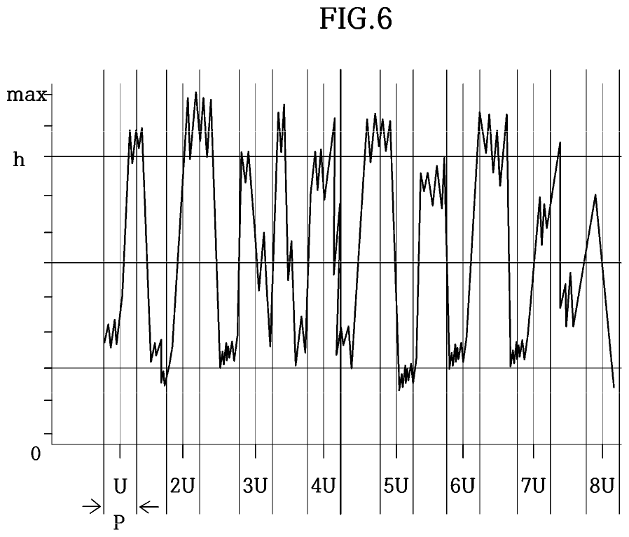

According to various embodiments, in performing the normalization operation of the diagnosis system 100, some of the feature values extracted from the sensed values may be omitted (or deleted, excluded, etc.). For example, the diagnosis system 100 may omit the feature value corresponding to a specified condition based on at least one component constituting the feature value, e.g., the feature value extraction point and/or the feature value value. Hereinafter, an embodiment of extracting some data of feature values will be described with reference to FIG. 6.

The diagnosis system 100 extracts feature values based on the sensed values identified over time after starting the vehicle. And FIG. 6 may show a part of a graph for expressing feature values (y-axis) extracted with respect to time flow (x-axis) in the diagnosis system 100 according to an embodiment of the present invention.

Referring to FIG. 6, when the extraction time unit value u is determined as the first unit value, the diagnosis system 100 may extract a specific feature value corresponding to each first unit value and omit the remaining feature values. According to an embodiment, when the first unit value is set to 5 seconds, the diagnosis system 100 may extract a specific feature value to be identified at a time point every 5 seconds (e.g., 5 seconds, 10 seconds, 15 seconds, etc.) based on the starting time point (e.g., 0), and omit the remaining feature values.

Here, the starting time point may refer to the time point (s) at which the diagnosis system 100 starts processing the scaling algorithm. The starting time point may be set to a time point (e.g., 0) at which feature values are extracted or a scaling algorithm is started to be performed, or a time point.

In the case of a vehicle, problems and symptoms are more likely to occur in a motor to which force is applied in an acceleration/deceleration situation than in a constant speed driving situation. In order to reflect this point, the diagnosis system 100 may control the setting of an extraction time unit value for extracting a specific feature value for performing a normalization operation among feature values according to the vehicle's driving conditions. For example, when the extraction time unit value in the constant speed driving situation is the first unit value, the diagnosis system 100 may set an extraction time unit value in an operation of the driver stepping on the brake as a preset second unit value smaller than the first unit value. At this time, in setting the extraction time unit value as the second unit value, the diagnosis system 100 may classify and set the second unit value in stages according to the degree of braking.

In addition, when the extraction time unit value in the constant speed driving situation is the first unit value, the diagnosis system 100 may set an extraction time unit value in an operation of the driver stepping on the accelerator as a preset third unit value smaller than the first unit value. When the extraction time unit value is set as the third unit value, the diagnosis system 100 may classify and set the third unit value in stages according to the degree of stepping on the accelerator and/or the acceleration.

According to another embodiment, an extraction time point for extracting a specific feature value among feature values may be set as a section (hereinafter referred to as a normalized interval) composed of an extraction time unit value u and an extraction time range value p. For example, when the normalization interval is set to the first unit value and the first range value, the diagnosis system 100 may extract a specific feature value identified within a first range value including the first unit value and omit the remaining feature values.

According to one embodiment, when the set first unit value is 5 seconds and the first range value is 2 seconds, the diagnosis system 100 may extract a specific feature value identified in a normalization interval of every 2 seconds including a time point every 5 seconds based on a start time point (e.g., 0), and omit the remaining feature values.

More specifically, in the normalization interval, the first unit value may be set to be located before, after, or in the middle of the first range value. For example, when the first unit value is 5 seconds and the first range value is 2 seconds, in a state where the starting time point is 0, the diagnosis system 100 may extract a specific feature value identified at 3 seconds to 5 seconds, 8 seconds to 10 seconds, 13 seconds to 15 seconds, and the like. In this case, the diagnosis system 100 may extract specific feature values identified at 4 to 6 seconds, 9 to 11 seconds, 14 to 16 seconds, and the like. Alternatively, the diagnosis system 100 may extract specific feature values identified at 5 to 7 seconds, 10 to 12 seconds, 15 to 17 seconds, and the like.

According to one embodiment of the present invention, in a state in which two or more feature values are extracted, the diagnosis system 100 may set a plurality of normalization times based on an extraction time unit value (e.g., 5 seconds) corresponding to a preset time interval. For example, 5 seconds, 10 seconds, 15 seconds, 20 seconds, etc. may correspond to the normalized time based on 0 second (the starting reference value may be different).

In addition, the diagnosis system 100 may determine a plurality of normalization intervals corresponding to a preset extraction time range value (e.g., 2 seconds) while including the plurality of normalization times, respectively. Here, each of the plurality of normalization intervals may include 5 seconds to 7 seconds (or 3 seconds to 5 seconds), seconds to 12 seconds (or 8 seconds to 10 seconds), 15 seconds to 17 seconds (or 13 seconds to 15 seconds), and the like.

As described above, in a state in which the normalization interval is set, the diagnosis system 100 may extract first specific feature values included in a plurality of normalization intervals from among two or more feature values. Further, the diagnosis system 100 may convert the first specific feature values into first scaled feature values based on a scaling algorithm and determine the state of the motor based on the first scaled feature values.

Specifically, among several feature values, feature values included in the normalization interval may be extracted and set as a first specific feature value. Next, the diagnosis system 100 converts the first specific feature values into first scaled feature values based on a scaling algorithm, and determines the state of the motor based on the converted first scaled feature values. A process of determining the state of the motor will be described later.

In addition, when the extraction time unit value (e.g., 5 seconds) and the extraction time range value (e.g., 2 seconds) are set, the diagnosis system 100 may change the start point of each of a plurality of normalization intervals. For example, when the existing normalization intervals are 5 seconds to 7 seconds, 10 seconds to 12 seconds, and 15 seconds to 17 seconds, when the start time of each of the plurality of normalization intervals is changed, the plurality of normalization intervals may be changed to 6 seconds to 8 seconds, 11 seconds to 13 seconds, 16 seconds to 18 seconds, and the like. That is, each section is moved while the distance between each section (extraction time unit value) and the length of each section (extraction time range value) are fixed.

Next, the diagnosis system 100 sets the feature values included in the plurality of changed normalization intervals as second specific feature values. Further, the diagnosis system 100 converts the second specific feature values into second scaled feature values based on a scaling algorithm. Also, the diagnosis system 100 may determine the state of the motor based on the second scaled feature value.

In other words, the diagnosis system 100 may change the start point, which is a criterion for extracting a specific feature value, through a scaling algorithm. According to various embodiments of the present disclosure, the diagnosis system 100 may perform a scaling algorithm process from the starting point of the vehicle. In this case, the diagnosis system 100 extracts a feature value from a sensed value that is confirmed over time, and at this time, a specific point in time at which the feature value is checked may be determined as the start point (0).

When setting a normalization interval for determining a specific feature value, the diagnosis system 100 determines the normalization interval based on a starting point as described above. That is, the diagnosis system 100 may change the normalization interval for extracting a specific feature value by changing the starting time point.

For example, the diagnosis system 100 may change the start point s by a positive (+) time or a negative (−) time. According to an embodiment, the diagnosis system 100 may extract a specific feature value by delaying the starting point by (+) 1 second according to setting information or through a scaling algorithm. When the first unit value is 5 seconds, the diagnosis system 100 may extract specific feature values identified in 6 seconds, 11 seconds, 16 seconds, etc., (which are normalization intervals set based on the time point delayed by 1 second from the start point (e.g., 0)).

When the start time of the scaling algorithm is delayed by (+) 1 second, the reference time point for determining the normalization interval may be determined as 1 second as described above.

The diagnosis system 100 may control the ratio of specific feature values to be extracted and feature values to be omitted (by changing the start point within a specified range as described above). It is possible to improve the data processing speed of the diagnosis system 100 and/or improve the diagnosis accuracy of the failure state by changing the start point within a specified range.

Here, the extraction time unit value, the extraction time range value, and the reference time for processing the start time are described as seconds, but are not limited thereto, and various units representing time may be applied.

In addition, in performing a normalization (or scaling) operation, the diagnosis system 100 may extract some specific feature values corresponding to an extraction feature range value in relation to the feature values and perform normalization based on the extracted feature values. For example, the diagnosis system 100 may determine a specific feature value to be scaled based on setting information for the second range value among feature values extracted from the sensed value. According to an embodiment, upon checking the second range value set to 90%, the diagnosis system 100 may apply a scaling algorithm to specific feature values that satisfy 90% based on the numerical values of the feature values.

In this case, when the feature value includes a negative (−) value, the diagnosis system 100 may apply a scaling algorithm to specific feature values that satisfy the conditions of 90% for positive (+) feature values and 90% for negative (−) feature values.

At this time, the diagnosis system 100 may determine feature values in ascending or descending order based on the setting information when applying the second range values to feature values. For example, when it is set to apply the second range value (e.g., 90%) in ascending order, the diagnosis system 100 may determine a specific feature value that satisfies 90% in a positive (+) direction from a reference value (e.g., 0) and/or a specific feature value that satisfies 90% in a negative (−) direction from a reference value (e.g., 0).

In this case, the diagnosis system 100 may determine specific feature values corresponding to the second range value from values included in the second range value compared to the maximum value of the component constituting the corresponding feature value. Alternatively, the diagnosis system 100 may determine specific feature values corresponding to the second range value from values included in the second range value compared to the number of specific feature values corresponding to the second range value.

As described above, although the diagnosis system 100 performs an operation of extracting some specific feature values based on a specified condition from feature values, it is described that a scaling operation is performed after extracting some of the feature values, the diagnosis system 100 may extract some specific feature values while performing the scaling operation. Alternatively, the diagnosis system 100 may extract some scaled specific feature values from among the scaled feature values after completing the scaling operation.

According to an embodiment of the present invention, the scaling algorithm may be implemented in an AI module. The diagnosis system 100 may learn a scaling algorithm using the extracted feature values as input values, and convert the extracted feature values into scaled feature values using the learned scaling algorithm. Here, the scaling algorithm used for learning may include an algorithm pre-learned based on the data of the vehicle for learning and the vehicle for correct answers.

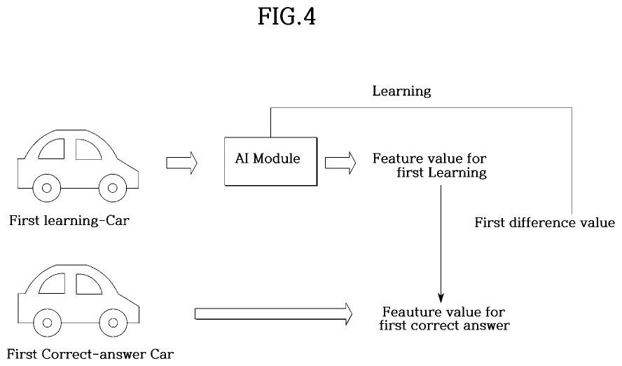

For example, the diagnosis system 100 may apply at least a part of the learning operation described in FIG. 4 in performing the learning process. For example, the diagnosis system 100 may learn the AI module based on the scaled feature values determined based on the prepared feature values of the vehicle for learning, the feature values of the vehicle for correct answers, and the feature values of the vehicle for correct answers.

The diagnosis system 100 compares the scaled feature value for correct answer converted based on the feature value of the vehicle for correct answer and the scaled feature value for learning converted based on the feature value of the learning vehicle to obtain a difference value. The diagnosis system 100 may update the scaling algorithm parameters of the AI module based on the difference value.

In step S307, the diagnosis system 100 may set a label for the state of the motor to the scaled feature value based on the learned labeling algorithm. More specifically, the state of the motor may be determined based on the learned labeling algorithm and scaled feature values, and a label indicating the state of the motor may be set to the scaled feature value corresponding to the state of the motor.

Here, the labeling operation of the diagnosis system 100 can be described as an operation of determining a state of a motor based on scaled feature value data. The labeling algorithm can be processed in the AI module.

The diagnosis system 100 may determine the state of the motor as a safe state, a failure-expected state, or a failure state based on the scaled feature value data. According to various embodiments of the present disclosure, a failure state does not necessarily mean a device is damaged, and may mean a state outside the range of a normal state or a state in which an abnormality has occurred, requiring inspection.

The diagnosis system 100 may determine the range of scaled feature values for determining the state of the motor based on the scaled feature value data based on the artificial intelligence algorithm of the AI module.

The diagnosis system 100 determines the state of a motor corresponding to a scaled feature value based on a labeling algorithm learned with respect to a preset range for determining each motor state. In addition, the diagnosis system 100 may label the determined state of the motor in the corresponding scaled feature value data. Here, the diagnosis system 100 may determine the state of the motor based on the scaled feature value and the set reference value.

Here, the reference value may be set in advance as a criterion for comparing the size with the extracted feature value. For a car in which a (normal or abnormal) state of a mounted motor has been determined in advance, a feature value of the motor of the car can be checked in advance (by using the formula: Feature Value=Ax+By+Cz+D), and a reference value can be set based on the feature value.

For example, based on the database, if a motor of a Vehicle A (measured temperature: t+1) is in an abnormal state (or a failure state) and the motor of a Vehicle B (measured temperature: t) is in a normal state (of a safe state), the reference value can be preset to a value between the scaled feature value of the Vehicle B (the measured temperature t is applied to the formula) and the scaled feature value of the Vehicle A (the measured temperature t+1 is applied to the formula).

Assuming that the minimum and maximum values of the normalized data are 0 and 1, in case the reference value is preset to 0.5, the diagnosis system 100 is able to determine that the motor of the car is in an abnormal (or failure) state when the scaled feature value of the car is greater than 0.5 and the motor of the car is in a normal (or safe) state when the extracted feature value of the car is less than or equal to 0.5. On the other hand, depending on the setting, the diagnosis system is able to determine that the motor of the car is in an abnormal state when the scaled feature value is less than the reference value.

In addition, it can be assumed that customized reference values can be classified into a plurality of classes based on the conditions of a car. The plurality of classes may include a first class, a second class, and the like.

Here, the conditions of a car may include a car manufacture year, an ambient temperature of a car, and the like. For example, cars older than 5 years may correspond to the first class while and cars less than 5 years may correspond to the second class, or cars at an ambient temperature of 20 degrees or higher may correspond to the first class while cars at an ambient temperature less than 20 degrees may correspond to the second class.

Of course, the plurality of classes is not limited to the first and second classes, and other additional classes (e.g., third class, fourth class, and the like) may exist. In addition, the conditions of a car may also include factors other than a car manufacture year and an ambient temperature thereof.

In addition, it can be assumed that a customized reference value is set for each class. Here, the customized reference value is an object to be compared with a scaled feature value, and can be a criterion to determine whether a motor and the like (driving system) is in a safe state (or a normal state) or a failure state (or an abnormal state).

Specifically, in the reference value for determining a failure-expected state (or a normal state) and a failure state (or an abnormal state), it can be assumed that the reference value corresponding to the first class is set as a first reference value, and the reference value corresponding to the second class is set as a second reference value different from the first reference value. In this case, when a car corresponds to the first class, the diagnosis system 100 is able to determine whether the motor is in the failure-expected state or the failure state based on the scaled feature value and the first reference value.

For example, it may be determined whether the motor of the car is in a failure state in case the scaled feature value is greater than the first reference value or in a failure-expected state in case the scaled feature value is smaller than the first reference value.

In addition, when a car corresponds to the second class, the diagnosis system is able to determine whether the motor is in a failure-expected state or a failure state based on the scaled feature value and the second reference value. For example, it may be determined that the motor of the car is in a failure state in case the scaled feature value is greater than the second reference value and in a failure-expected state in case the scaled feature value is smaller than the second reference value.

In case that a car manufacture year is included in the conditions of a car and the car corresponding to the first class is manufactured earlier than the car corresponding to the second class, the first reference value may be greater than the second reference value. That is, the reference value of an older car is smaller than the reference value of a car manufactured earlier.

In the case of a car with an older model year, even if it is not in an abnormal state, it may be in a state in which at least of one among temperature, voltage, and current increases even in normal times, so it is necessary to determine more flexibly the motor in a failure-expected state or a failure state.

For example, since the first reference value (b) of the first class is greater than the second reference value (a) of the second class, the abnormal occurrence range may also be different by class. A car corresponding to the first class may be in a failure state if the scaled feature value is greater than b, and a car corresponding to the second class may be in a failure state if the scaled feature value is greater than a.

As a result, the range corresponding to the failure state may be determined to be wider as the car is manufactured earlier or located in a lower temperature area, wherein the car corresponds to the second class.

As described above, each of the scaled feature values includes information enabling the determination on the state of the corresponding motor, for example, a safe state or a failure state, and the diagnosis system 100 is able to determine the state of the motor indicated by the scaled feature value using the set reference value.

According to various embodiments, It has been described above that the diagnosis system 100 determines the safe state or the failure state of the motor based on the scaled feature values. However, in some cases, based on the scaled feature value, the state of the motor may be further subdivided and determined as whether the motor is in a failure state, whether the motor is in a failure-expected state where failure is expected within a certain period (e.g., 1 year), or whether the motor is in a safe state.

Specifically, two or more reference values (e.g., e and f) may be preset. And, based on the reference value and the scaled feature value, it is possible to determine a safe state, an failure-expected state, and a failure state.

The diagnosis system 100 may determine that the mounted motor is in a safe state when the scaled feature value is equal to or smaller than the reference value e. The diagnosis system 100 may determine that the installed motor is in a failure-expected state when the scaled feature value is greater than the reference value e and less than or equal to the reference value f. In addition, the diagnosis system 100 may determine that the mounted motor is in a failure state when the scaled feature value is greater than the reference value f.

The diagnosis system 100 may determine the state of a motor in the vehicle based on the state of the motor determined for each of the scaled feature values. For example, the diagnosis system 100 checks the ratio of motor states (or each number of motor states) that are identified in correspondence with scaled feature values during a recent specified time range. And the state of the motor having the largest value may be determined as the state of the motor in the vehicle (or the latest state of the motor).

According to one embodiment, when the ratio of the normal state, the failure-expected state, and the failure state of the motor confirmed through the scaled feature values for the last 1 hour is 2:7:1, the failure-expected state having the largest ratio may be determined as the state of the motor in the vehicle.

However, the present invention is not limited to the above-described embodiment. For example, the recently designated time range may be determined based on at least some units of minutes, days, weeks, or years according to setting information as well as hours.

In addition, in determining the state of the motor in the vehicle, it is not limited to determining the state of the motor based on the ratio of the normal state, the failure-expected state, and the failure state of the motor identified through scaled feature values. An average of the scaled feature values may be obtained, and a state of a motor corresponding to the average value may be determined as the state of the motor in the vehicle.

Here, the diagnosis system 100 may set the above reference value using a learned AI module (which may be different from the feature value extraction AI module). That is, after processing data obtained from measured values such as vehicle temperature, extracted feature values, and scaled feature values, while passing these values through the AI module, it is possible to repeat the learning process of extracting the reference values for distinguishing each state boundary of the motor. Of course, the reference value may be arbitrarily set without going through a learned AI module or the like.

In addition, in determining the state of the motor in the vehicle based on the scaled feature value and/or the set label, when the failure-expected state of the motor is determined, the diagnosis system 100 may further determine a predetermined failure-expected period. At this time, the predetermined period may be set in advance and may be changed according to circumstances.

For example, the diagnosis system 100 may determine a predetermined period of time during which motor failure is expected, on a daily, weekly, monthly and/or yearly basis, based on setting information, scaled feature values, and a database associated with other vehicles.

According to an embodiment, the diagnosis system 100 can check predetermined data related to the time of failure of the corresponding motor of the same or similar car as the corresponding car and the period required until the failure state based on the database of a correct-answer car.

The diagnosis system 100 is able to determine a failure-expected period until the failure of the corresponding motor occurs by comparing data of manufacture years (or class), total mileage, and/or scaled feature values of a car with those of a correct-answer car. At this time, the data of the correct-answer car may be data of a plurality of correct-answer cars.

The diagnosis system 100 may use feature value data extracted from sensors as well as scaled feature values when determining a predetermined period in which a failure is expected.

In addition, when the failure-expected state of the motor is determined, the diagnosis system 100 is able to determine when to inspect (e.g., repair or replace) the motor based on the failure-expected period.

At this time, the diagnosis system 100 is able to determine the time of inspection of the motor in days, weeks, months, and/or years based on the class of a car, a role of a motor and feature values included in the abnormal clusters and/or shorten or extend a failure-expected period in which a failure of the motor is expected, and determine that an urgent inspection is required when confirming that the inspection time is within a designated period.

According to one embodiment, for a motor set to require an urgent inspection when a car corresponds to a first class, a motor is related to the operation of the car, and a failure-expected period where the failure of the motor is expected is within one week, a diagnosis system 100 is able to determine that a motor requires urgent inspection when the car corresponds to a first class, there is no history of repair or replacement of a motor, the motor related to regenerative breaking is in a failure-expected state, and a failure-expected period wherein the failure of the motor is expected based on feature values included in an abnormal cluster is for three days.

On the other hand, by presetting at least three reference values in the case of frequently used cars and cars (for example, taxi, kindergarten bus, etc.) in which safety issues should be considered more strictly, three or more reference values are set in advance, the diagnosis system is able to determine the state of the installed motor as a normal state, a state in which failure is expected within 6 months, a state in which failure is expected within 3 years, and a failure state. That is, the diagnosis system is able to determine the state of the motor over a specific predetermined period of time in more detail.

The diagnosis system 100 may generate a guide message including the state of the motor confirmed as described above and/or an expected period of failure of the motor, and store it in the car's storage, or output it through a display and/or a speaker. According to various embodiments of the present disclosure, although not described with reference to FIG. 3, the diagnosis system 100 may update a labeling algorithm based on feature values for which labels are set.

For example, the diagnosis system 100 may learn the labeling algorithm applied in step S307 using scaled feature values of vehicle, labels set to scaled feature values of vehicle, scaled feature values of vehicle for correct answer as comparison group, and label data set to scaled feature values of vehicle for correct answer.

When learning the labeling algorithm, the diagnosis system 100 may learn the labeling algorithm by performing the same or similar process as at least some of the operations for learning the AI module of FIG. 4. According to one embodiment, the diagnosis system 100 compares scaled feature values of the vehicle for correct answers and the set labels with scaled feature values of the vehicle and the set labels for determining the state of the motor to obtain a difference value, and the diagnosis system 100 may update the labeling algorithm parameters of the AI module based on the difference value.

FIG. 4 is a diagram illustrating a learning process of an AI module according to an embodiment of the present invention. Hereafter, I will explain the learning process of the AI module for extracting feature values from sensed values with FIG. 4.

First, for learning of the AI module, it can be assumed that a plurality of cars for learning is classified into classes (e.g. first class, second class, etc.) matched based on each condition (e.g. manufacture year, ambient temperature).

Next, the diagnosis system 100 is able to extract feature values for first learning from the plurality of first learning cars included in the first class by using the AI module. In addition, the diagnosis system 100 is able to acquire feature values for a first correct answer from the correct-answer car included in the first class.

Here, the feature value for the first correct answer may correspond to a value representing the actual state of the correct-answer car (abnormal state or normal state confirmed based on a temperature, a voltage, and/or a current). In the case of a car for an actual correct answer, it corresponds to a car for which a malfunction has already been recognized, and accordingly, the feature value for the first correct answer may also be specified as a value smaller than the reference value (for example, if the reference value is preset to be 10, the feature value for the first correct answer is specified as one of 10 or smaller numbers).

In addition, the diagnosis system 100 is able to acquire a first difference value by comparing the feature value for the first correct answer and the feature value for the first learning, and then update parameters of the AI module based on the first difference value. That is, the diagnosis system 100 is able to perform a process of checking the difference between the feature value for the first correct answer and the feature value for the first learning, and updating the parameters of the AI module so that there is no such difference (so that the feature value for the first learning matches the feature value for the first correct answer).

The process of updating the parameters of the AI module as described above may be repeatedly performed, and as the number of performing the process increases, more accurate determination (extraction of feature values) of the AI module may be possible.

Also, as in the first class, the diagnosis system 100 is able to extract feature values for second learning from a plurality of second learning-cars included in the second class by using the AI module.

In addition, the diagnosis system 100 is able to acquire a feature value for a second correct answer from the second learning-cars included in a second class, and compare it with the feature value for the second learning to acquire a second difference value. In addition, the diagnosis system is able to perform a process of updating parameters of the AI module based on the second difference value.

As described above, the diagnosis system is able to repeatedly update the parameters of the AI module by using the learning-cars and the correct-answer cars included in the first class and the second class, respectively, thus performing the learning of the AI module through this.

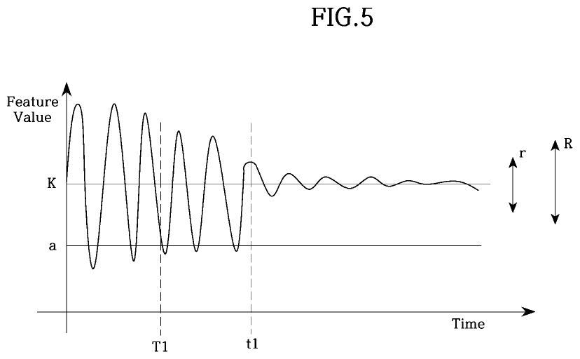

FIG. 5 is a diagram illustrating a process of extracting feature values according to an embodiment of the present invention.

As described above, the feature value extracted through the AI module or the like are be extracted by time period and implemented as a two-dimensional graph (x-axis: time, y-axis: feature value) (see FIG. 6).

At this time, the feature value extracted through the calculation formula using conversion values such as temperature, current, and voltage as input values is in the form of a wave, which fluctuates at first and then gradually converges to a constant value.

At this time, the diagnosis system 100 extract no feature values when the distance (wave height) between the ridge and furrow of the corresponding wave form is greater than r, but extract a median value (converged value) between the ridge and furrow as a feature value when the distance is smaller than r. Referring to FIG. 5, since t1 (time), the wave height has become smaller than r, and the diagnosis system 100 is able to extract the feature value of the car as K after t1. Here, since K is greater than the reference value a, it can be determined that the car's motor is in an abnormal state.

At this time, in extracting the feature value K, the diagnosis system 100 may extract a plurality of feature values by setting the time value for determining the median value between the crest and the trough to a designated time unit (or period).

In general, waves related to feature values fluctuate immediately after starting the engine, immediately after stepping on the brake, and immediately after stepping on the accelerator pedal, and the diagnosis system 100 extracts a feature value when the wave converges to a certain value after a certain time (for example, t1) and compares the feature value with the reference value to determine whether the motor is in an abnormal state or not.

According to an embodiment of the present invention, the size of r, which is a factor determining a feature value, may vary according to the current situation of the car (e.g., immediately after starting the engine, immediately after stepping on the brake, immediately after stepping on the accelerator pedal, etc.). As it is necessary to quickly determine whether or not there is an abnormality since immediately after stepping on the brake may be more dangerous than other times when driving a car

Accordingly, the diagnosis system 100 is able to set the size of r larger than other times at the time immediately after stepping on the brake, and may set the size of r as R as shown in FIG. 5 for convenience of explanation.

In such a state, immediately after stepping on the brake, the feature value fluctuated in the form of a wave, and the distance (wave height) between the ridge and the furrow became smaller than R after T1, and the diagnosis system 100 is able to extract a feature value for the motor of the car after T1, and compare it with a reference value a to determine an abnormal state.

As a result, as shown in FIG. 5, immediately after stepping on the brake, the feature value may be determined at the time point T1, which is earlier than t1, and accordingly, the abnormality can be quickly determined. Therefore, a driver can determine quickly if there is an abnormality and take quicker action.

In addition, depending on the case, the diagnosis system 100 is able to set the size of r to be smaller than other times at the time immediately after starting the engine. This is because the time immediately after starting the engine may be a time when there is more room than other times, so it is possible to accurately determine whether or not there is an abnormality. Therefore, after waiting until the fluctuation of the feature value disappears (later than the time t1), the diagnosis system 100 is able to extract the feature value for the motor of the car, and compares it with the reference value a to determine whether the state of motor is a normal state or an abnormal state.

That is, the diagnosis system 100 may extract, as feature values, singular points of the motor that occur after a specified point in time after the operation of a specific car function (e.g., starting, braking, accelerating pedal, etc.) is performed, and determine the state of the motor based on this.

In addition, the feature value to be extracted may represent the shape of a converging wave as described above, but may represent a feature based on an aperiodic state different from the shape of a wave according to various variables such as the state of the motor and the driving of the vehicle, and the diagnosis system 100 may extract these aperiodic features as feature values.

As described above, the diagnosis system 100 installed in a car (in the form of a PHM soc) of the present invention is able to diagnose the state of the installed motor in real time, and deliver the result to a driver through an infotainment for a car. That is, the diagnosis system 100 is able to prevent accidents by conveying information to the driver, such as whether there is an abnormality in the motor of the car and when the motor should be repaired, and the driver can economically determine a motor repair plan.

In addition, the diagnosis system 100, when the state of the motor is determined as a failure state or a state in which failure is expected, is able to guide a nearby repair shop through the car infotainment, or automatically provide car information (for example, location, condition, etc.) to a nearby and/or designated repair shop.

According to various embodiments of the present invention, the present invention obtains an effect of diagnosing the state of a motor in a car through a diagnosis system located in the car, and determining not only whether the motor has failed but also a failure-expected period.

In addition, according to various embodiments of the present invention, the amount of data and the processing range can be reduced by processing the extracted data through a normalization process, and thus the speed at which the diagnosis system diagnoses the state of the motor in a vehicle can be improved.

the present invention obtains an effect of predicting the state of a motor more accurately through learning of an AI module by monitoring the state of a driving system in a car in real time using AI technology.

In addition, data density may be increased through scaling of feature values extracted from sensed values, and through this, data representing a motor state may be patterned. Through this, the diagnosis system can improve the speed of diagnosing the state of the motor in the vehicle.

The above-described exemplary embodiments of the present invention may be implemented in the form of program commands that are executable through various computer components, and recorded on a computer-readable medium. The computer-readable medium may include program commands, data files, data structures, or the like solely or in combination. The program commands recorded on the computer-readable medium may be known and available to those skilled in the field of computer software. Examples of the computer-readable recording medium include a hardware device specially configured to store and execute program commands such as a hard disk, a read-only memory (ROM), a random access memory (RAM), a flash memory, etc. Examples of the program commands include not only machine language code generated by a compiler but also high-level language code that is executable by a computer using an interpreter or the like. The hardware device may be configured to operate as one or more software modules to perform operations according to the present invention, and vice versa.

Although the present invention has been described with specific details, such as specific components, limited embodiments and drawings, these are provided to facilitate general understanding of the present invention, and the present invention is not limited to the embodiments. Those skilled in the art can make various modifications and alterations from the description.

Therefore, the idea of the present invention should not be limited to the above-described embodiments, and it is to be noted that the spirit of the present invention encompasses not only the following claims but also all modifications equivalent to the claims.

What is claimed is:

1. A method for monitoring failure of a motor in a car based on a scaling algorithm when a system for monitoring failure of the motor is mounted in the car and includes a sensing module sensing the state of the motor, the method comprising:
(a) acquiring sensed values by sensing the state variables of the motor by the sensing module;
(b) extracting two or more feature values by converting the sensed values acquired by the sensing module;
(c) converting the two or more feature values into scaled feature values based on at least one scaling algorithm; and
(d) determining a state of the motor based on a learned labeling algorithm and the scaled feature value, and setting a label representing the state of the motor to the scaled feature value corresponding to the state of the motor.

2. The method according to claim 1,
wherein the two or more feature values are extracted,
setting a plurality of normalization times based on the extraction time unit value corresponding to a preset time interval; and
determining a plurality of normalization intervals corresponding to a preset extraction time range value, each normalization interval includes each normalization time.

3. The method according to claim 2,
extracting first specific feature values included in the plurality of normalization intervals from among the two or more feature values;
converting the first specific feature values into first scaled feature values based on the scaling algorithm; and
determining the state of the motor based on the first scaled feature value.

4. The method according to claim 3,
wherein the extraction time unit value and the extraction time range value are set,
changing the start time of each of the plurality of normalization intervals;
extracting second specific feature values included in the plurality of changed normalization intervals;
converting the second specific feature values into second scaled feature values based on the scaling algorithm; and
determining the state of the motor based on the second scaled feature value.

5. The method according to claim 1,
wherein the step (c) further comprising:
extracting a part of the scaled feature value corresponding to a predetermined range in relation to the numerical value of the scaled feature value.

6. The method according to claim 1, further comprising:
(e) updating the labeling algorithm based on the feature values for which the label is set, and resetting the feature values that classify the state of the motor based on said updated labeling algorithm;

7. A system for monitoring failure of a motor in a car based on a scaling algorithm, comprising:
a sensing module for sensing a state variables of the motor in the car and acquiring sensed values;
a motor state determination module for extracting two or more feature values by converting the sensed values acquired by the sensing module, and for converting the two or more feature values into scaled feature values based on at least one scaling algorithm, and for determining the state of the motor based on the learned labeling algorithm and the scaled feature value, and for setting a label representing the state of the motor to the scaled feature value corresponding to the state of the motor,
wherein the system is mounted in the car.
